(19) United States
(12) Patent Application Publication
(10) Pub. No.: US 2008/0137775 A1
(43) Pub. Date: Jun. 12, 2008

(54) METHOD AND APPARATUS FOR HIERARCHICAL MODULATION AND DEMODULATION IN DIGITAL BROADCASTING SYSTEM

(76) Inventors: Tae Hoon KIM, Seoul (KR); In Ki LEE, Busan (KR); Seung Hyun CHOI, Daejeon (KR); Cheon In OH, Daejeon (KR); Dae Ig CHANG, Daejeon (KR); Ho Jin LEE, Daejeon (KR); Sung Hoon LEE, Seoul (KR); Goon Seop LEE, Seoul (KR); Dong Hahk LEE, Seoul (KR); Jae Hwang YU, Seoul (KR)

Correspondence Address: LADAS & PARRY LLP, 224 SOUTH MICHIGAN AVENUE, SUITE 1600, CHICAGO, IL, 60604, US

(21) Appl. No.: 11/931,074

(22) Filed: Oct. 31, 2007

(30) Foreign Application Priority Data
Dec. 7, 2006 (KR) 10-2006-0123861
May 18, 2007 (KR) 10-2007-0048615

(51) Int. Cl. H04L 27/20; H03D 3/22; H04L 27/22

(52) U.S. Cl. 375/308; 375/329

(57) ABSTRACT

Provided are a method and apparatus for hierarchical modulation and demodulation in a Digital Multimedia Broadcasting (DMB) system. The method for hierarchical modulation in a digital broadcast signal transmitter includes the steps of: receiving a first broadcast signal and a second broadcast signal from outside, and encoding the broadcast signals by a first method and a second method, respectively; synthesizing the encoded first and second broadcast signals; determining a modulation point using a constellation diagram of an I-Q plane corresponding to the synthesized signal; and hierarchically phase-shift modulating the synthesized signal using the determined modulation point. Here, in the I-Q plane, the modulation point is deviated by a predetermined deviation angle from a phase axis passing through a modulation point of the first broadcast signal and an origin of the I-Q plane.

### CROSS-REFERENCE TO RELATED APPLICATION

This application claims priority to and the benefit of Korean Patent Application No. 2006-123861, filed Dec. 7, 2006, and No. 2007-48615, filed May 18, 2007, the disclosure of which is incorporated herein by reference in its entirety.

### BACKGROUND

1. Field of the Invention

The present invention relates to a method and apparatus for hierarchical modulation and demodulation in a Digital Multimedia Broadcasting (DMB) system.

The present invention has been produced from the work supported by the IT R&D program of MIC (Ministry of Information and Communication)/IITA (Institute for Information Technology Advancement) [2005-S-013-02, Development of Broadband Adaptive Satellite Communications and Broadcasting Convergence Technology] in Korea.

2. Discussion of Related Art

Lately, with the development of information and communication technology, it can be difficult to distinguish communication service from broadcasting service. Thus, a service that is coming into the limelight can provide both mobile broadcasting service and mobile communication service. Satellite DMB service capable of satisfying such a need provides various multimedia broadcasting services, i.e., video, audio, data, etc., via a satellite.

According to the satellite DMB service, it is possible to receive mobile service without a hitch using a portable receiver, etc. Also, in a region in which service cannot be directly received from a satellite, it is possible indirectly receive service using a complementary terrestrial repeater, and so on.

As the satellite DMB service is provided, information needed by consumers increases. However, it is difficult to increase transmission capacity without changing satellite DMB service facilities.

### SUMMARY OF THE INVENTION

The present invention is directed to a method and apparatus for hierarchical modulation and demodulation in a digital broadcasting system.

The present invention is also directed to a method capable of improving transmission efficiency through hierarchical modulation and a demodulation method in a currently employed system.

One aspect of the present invention provides a method for hierarchical modulation in a digital broadcast signal transmitter, the method comprising the steps of: receiving a first broadcast signal and a second broadcast signal from outside, and encoding the broadcast signals by a first method and a second method, respectively; synthesizing the encoded first broadcast signal with the encoded second broadcast signal; determining a modulation point using a constellation diagram of an I-Q plane corresponding to the synthesized signal; and hierarchically phase-shift modulating the synthesized signal using the determined modulation point. Here, in the I-Q plane, the modulation point is deviated by a predetermined deviation angle from a phase axis passing through a modulation point of the first broadcast signal and an origin of the I-Q plane.

The first broadcast signal may be demodulated by a Quadrature Phase Shift Keying (QPSK) demodulator and thus can be recognized, and the second broadcast signal may be recognized as noise by the QPSK demodulator. Also, the first broadcast signal may have a higher restoration reliability indicating a possibility of being restored by a demodulator than the second broadcast signal.

In addition, the first broadcast signal may be a satellite digital broadcast signal, the first method may be an encoding method for the satellite digital broadcast signal, the second broadcast signal may be an additional information signal of the satellite digital broadcast signal, and the second encoding method may be an encoding method determined according to a type of the additional information signal. Also, modulation performance for the hierarchically phase-shift-modulated first broadcast signal may be determined according to the deviation angle. Further, the deviation angle may be determined in consideration of a limit of Signal-to-Noise Ratio (SNR) of the first broadcast signal. Furthermore, the encoding by the first method may further comprise the steps of Reed-Solomon encoding and Code Division Multiplexing (CDM).

Another aspect of the present invention provides a method for hierarchical demodulation in a digital broadcast signal receiver, the method comprising the steps of: receiving a digital broadcast signal from outside; determining a demodulation point of the received digital broadcast signal using a constellation diagram of an I-Q plane corresponding to the received digital broadcast signal; hierarchically phase-shift demodulating the received digital broadcast signal using the demodulation point; separating the demodulated digital broadcast signal into a first broadcast signal and a second broadcast signal; and demodulating the first broadcast signal by a digital broadcasting method and the second broadcast signal by a predetermined method. Here, in the I-Q plane, the demodulation point is deviated by a predetermined deviation angle from a phase axis passing through a modulation point of the first broadcast signal and an origin of the I-Q plane.

The deviation angle may be determined in consideration of a limit of SNR of the first broadcast signal.

Still another aspect of the present invention provides a digital broadcast signal transmitter, comprising: a Reed-Solomon encoder for encoding a first broadcast signal; a byte interleaver for mixing the encoded first broadcast signal; a convolution encoder for re-encoding the mixed first broadcast signal; a first bit interleaver for remixing the re-encoded first broadcast signal; a second encoder for encoding a second broadcast signal; a second bit interleaver for mixing the encoded second broadcast signal; a code division multiplexer for multiplexing the first and second broadcast signals output from the first and second bit interleavers; and a hierarchical modulator for synthesizing and hierarchically phase-shift modulating the code-division multiplexed signals. Here, using a constellation diagram of an I-Q plane corresponding to the synthesized signal, the hierarchical modulator determines a modulation point in the I-Q plane deviated by a predetermined deviation angle from a phase axis passing through a modulation point of the first broadcast signal and an origin of the I-Q plane, and hierarchically phase-shift modulates the synthesized signal using the determined modulation point.

Yet another aspect of the present invention provides a digital broadcast signal receiver, comprising: a hierarchical demodulator for, using a constellation diagram of an I-Q plane corresponding to a received digital broadcast signal, determining a demodulation point of the received digital broadcast signal deviated by a predetermined deviation angle from a phase axis passing through a modulation point of a first broadcast signal and an origin of the I-Q plane, and hierarchically phase-shift demodulating the received digital broadcast signal using the demodulation point; a code division demultiplexer for code-division demultiplexing the signal demodulated by the hierarchical demodulator into the first broadcast signal and a second broadcast signal; a Reed-Solomon decoder for decoding the code-division demultiplexed first broadcast signal; and a second demodulator for decoding the code-division demultiplexed second broadcast signal.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 illustrates a satellite digital multimedia broadcasting (DMB) system to which the present invention is applied;

FIG. 2 schematically illustrates a method of modulating digital multimedia data in an earth station of a conventional satellite DMB system to which the present invention is applied;

FIG. 3 is a constellation diagram illustrating Quadrature Phase Shift Keying (QPSK) modulation according to a conventional DMB modulation scheme;

FIG. 4 schematically illustrates a method of modulating digital multimedia data in an earth station of a satellite DMB system according to an exemplary embodiment of the present invention;

FIG. 5 is a constellation diagram illustrating 8PSK hierarchical modulation according to an exemplary embodiment of the present invention; and

FIG. 6 illustrates a transmitter and a receiver of a satellite DMB system according to an exemplary embodiment of the present invention.

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. The following embodiments are described in order to enable those of ordinary skill in the art to embody and practice the present invention.

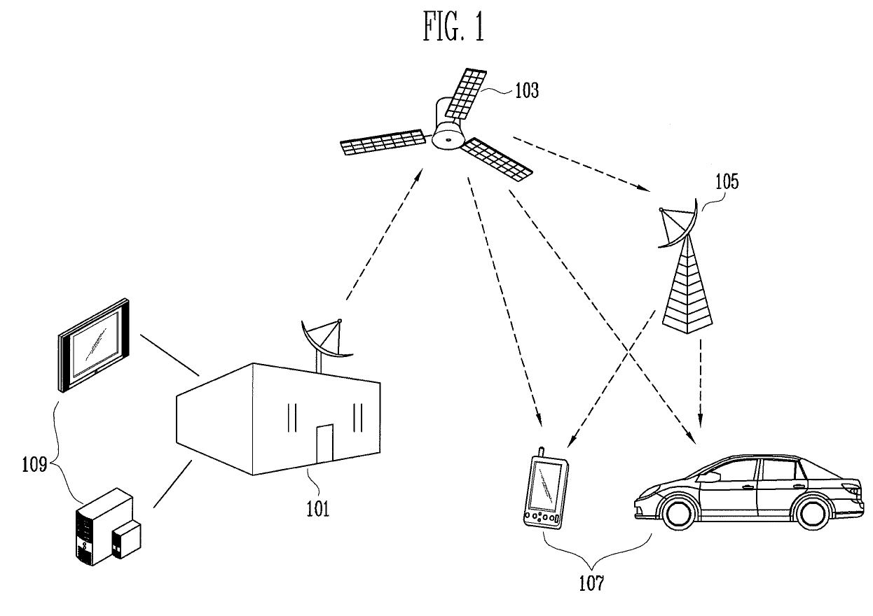

FIG. 1 illustrates a satellite Digital Multimedia Broadcasting (DMB) system to which the present invention is applied.

Referring to FIG. 1, the satellite DMB system comprises an earth station 101, a satellite 103, a complementary terrestrial repeater 105 and subscriber terminals 107.

The earth station 101 converts a content signal received from content providers 109 using a Code Division Multiplexing (CDM) scheme and transmits the converted signal to the satellite 103. The satellite 103 receiving the signal directly transmits the signal to the subscriber terminal 107 or indirectly transmits the signal to the subscriber terminal 107 in a shadow area, in which it is difficult to directly receive a signal due to geographical features, via the complementary terrestrial repeater 105.

Since the satellite DMB system transmits digital media broadcast using the satellite 103, it has advantages in that it is possible to receive the broadcast in a wide area with negligible geographic influence and receive various multimedia broadcast data regardless of whether it is a mobile environment or fixed environment.

FIG. 2 schematically illustrates a method of modulating digital multimedia data in an earth station of a conventional satellite DMB system to which the present invention is applied.

Referring to FIG. 2, first, a satellite DMB signal 211 is input from outside to a DMB encoder 201. The input satellite DMB signal 211 is converted into a digital signal 213 consisting of “0” and “1” by the DMB encoder 201. The digital signal 213 is input to a Quadrature Phase Shift Keying (QPSK) mapper 203 and thus is converted into an I-Q signal 215 that can be orthogonally modulated. Then, the I-Q signal 215 mapped in this way is modulated by an orthogonal modulator 205 and is transmitted to outside.

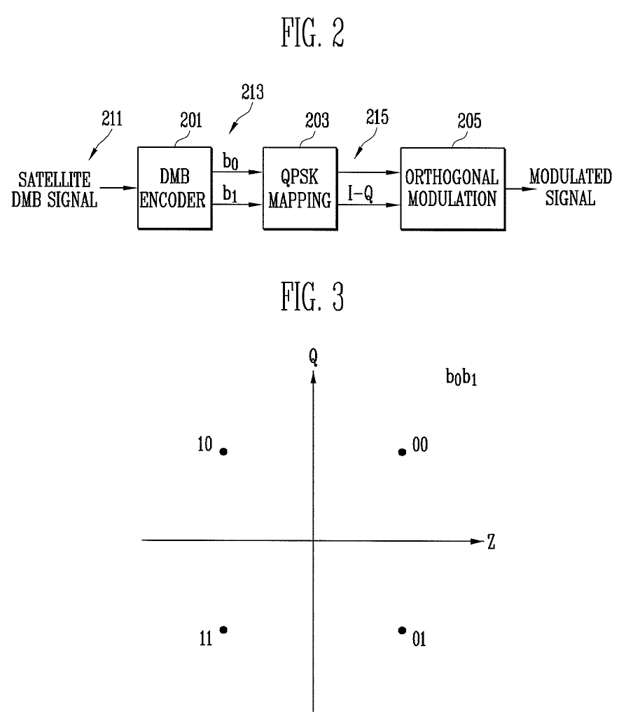

In such a method, the signal 215 mapped by QPSK is modulated, which consists of 4 points respectively existing in the quadrants of a constellation diagram shown in an I-Q coordinate system, as illustrated in FIG. 3. This conforms to the transmission standard of satellite DMB. The modulation device is designed according to such a method, and also a receiving device is designed to demodulate the QPSK-modulated signal.

FIG. 3 is a constellation diagram illustrating QPSK modulation according to a conventional DMB modulation scheme.

Referring to FIG. 3, a constellation diagram shows a digital signal mapped by QPSK in FIG. 2 in an I-Q plane.

Each point included in each quadrant of the plane conceptually denotes modulated data. In particular, the points of the respective quadrants are expressed as “00,” “10,” “11,” and “01” from the first quadrant to the fourth quadrant, which denote combinations of digital signals b₀ and b₁ input to the QPSK mapper 203 in FIG. 2.

Such a QPSK modulation scheme can transmit a higher amount of data in comparison with a general modulation method, but naturally has less transmission capacity than 8PSK, 16PSK and 16-Quadrature Amplitude Modulation (QAM) modulation schemes.

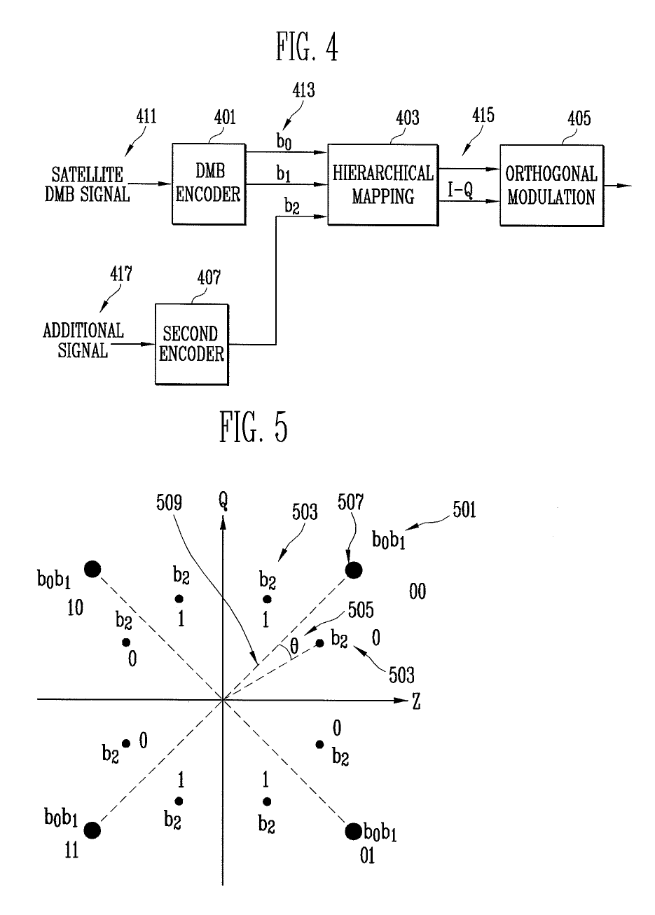

FIG. 4 schematically illustrates a method of modulating digital multimedia data in an earth station of a satellite DMB system according to an exemplary embodiment of the present invention.

Referring to FIG. 4, in the same manner as shown in FIG. 2, a satellite DMB signal 411 is converted into a digital signal 413 by a DMB encoder 401, input to a hierarchical mapper 403, converted into an I-Q signal 415, modulated by an orthogonal modulator 405, and transmitted.

However, in FIG. 4, an additional signal 417 is transmitted together with the conventional satellite DMB signal, unlike in FIG. 2.

The additional signal 417 is encoded by a second encoder 407 and then input to the hierarchical mapper 403 together with the digital signal 413 which is the encoded satellite DMB signal.

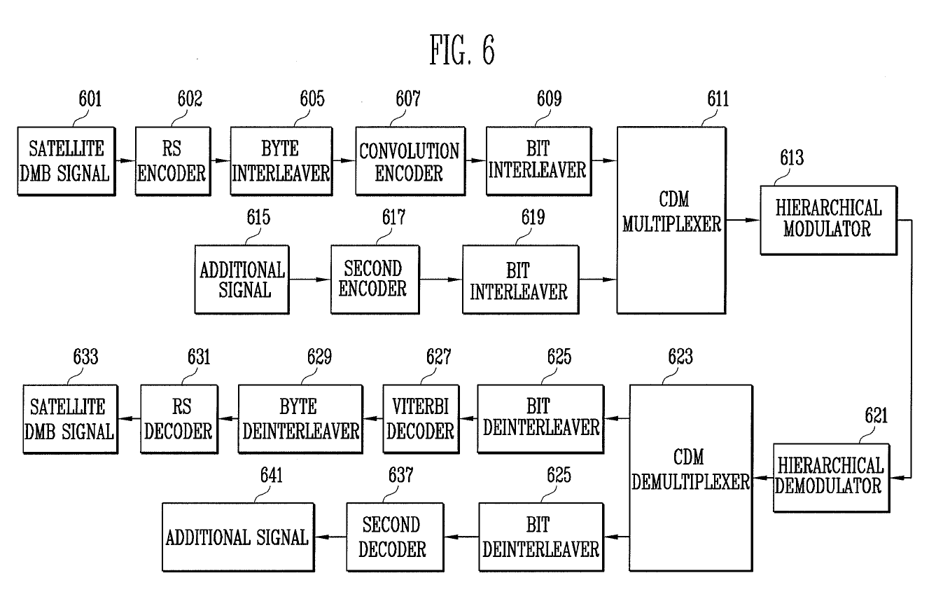

Here, the hierarchical mapper 403 maps signals b₀ and b₁ input from the DMB encoder 401 and a signal b₂ input from the second encoder 407 all by hierarchical 8PSK modulation. The constellation diagram of the mapped signal will be described in detail with reference to FIG. 5.

The mapped signal is converted into the I-Q signal 415, modulated by the orthogonal modulator 405, and transmitted.

In this case, since 8PSK modulation is not QPSK modulation conforming to the standard of a satellite DMB signal, transmission capacity increases in comparison with conventional QPSK modulation, but a demodulator may not be able to demodulate an 8PSK-modulated signal. However, when the 8PSK-modulated signal is modulated in the way described with reference to FIG. 5, a demodulator can perform demodulation without any problems.

Therefore, when a hierarchical modulation method according to the present invention is used, there is no problem in a conventional satellite DMB system. In addition, when a new demodulator is added, it is possible to additionally use data included in an additional signal.

FIG. 5 is a constellation diagram illustrating 8PSK hierarchical modulation according to an exemplary embodiment of the present invention.

Referring to FIG. 5, an 8PSK modulation scheme according to the present invention shows a different constellation diagram from a general 8PSK modulation scheme. In the constellation diagram of the general 8PSK modulation scheme, 2 modulation points exist on each of an I-axis and a Q-axis, one modulation point exists in each quadrant, and thus 8 modulation points exist.

On the other hand, the 8PSK modulation scheme according to the present invention has 2 modulation points in each quadrant, as shown in the drawing. In the constellation diagram of the 8PSK modulation scheme according to the present invention, respective modulation points 503 do not symmetrically exist, unlike the general 8PSK modulation scheme, but just exist at a position deviated from a phase axis 509 by a predetermined deviation angle 505, as shown in the drawing.

Here, the phase axis 509 indicates a virtual axis passing through a virtual modulation point 507 and the origin of the constellation diagram. The virtual modulation point 507 is a modulation point obtained by assuming that only signals b₀ and b₁ are input for phase shift modulation, that is, obtained upon QPSK modulation as shown in FIG. 3. In particular, the phase axis 507 has the same angle as a phase angle of each modulation point according to a conventional satellite DMB method and thus the angle will be π/4.

According to the hierarchical 8PSK modulation scheme, as shown in the constellation diagram, the signals b₀ and b₁ 501 is included in each quadrant, like a conventional QPSK modulation scheme, and the modulation points 503 of each quadrant have characteristics of a signal b₂ alone. Here, a clear modulation point of the signals b₀ and b₁ 501 cannot be shown in the constellation diagram by the hierarchical modulation scheme, but the signals b₀ and b₁ 501 can be demodulated using 2 modulation points included in each quadrant.

When a hierarchically 8PSK-modulated signal is demodulated by a conventional QPSK demodulation scheme, only the signals b₀ and b₁ among modulated signals are demodulated by the QPSK demodulation scheme. Here, the signals b₀ and b₁ wholly exist in each quadrant that is a conventional QPSK demodulation area, as shown in the constellation diagram of the hierarchically 8PSK-modulated signal according to the present invention. Therefore, a conventional QPSK demodulator also can demodulate a hierarchically 8PSK-modulated signal according to the present invention, and the signals b₀ and b₁ among signals modulated by the hierarchical 8PSK modulation scheme according to the present invention can be demodulated by a conventional DMB demodulator.

There may be some performance deterioration because the signal b₂ is recognized as noise. However, this problem can be solved by making the deviation angle 505 smaller than the maximum deviation angle corresponding to a link limit of Signal-to-Noise Ratio (SNR) that can be demodulated by a conventional DMB demodulator.

Here, the deviation angle 505 is previously determined by a user. For example, when the deviation angle 505 becomes 0, the modulation points 503 overlap on the phase axis 509 and finally becomes the same signal as a conventionally QPSK-modulated signal. On the other hand, when the deviation angle 505 is excessively large, the modulation points 503 may exist out of their quadrants, and there may be noise components alone. In other words, when the deviation angle 505 increases, noise components may excessively increase to demodulate the signals b₀ and b₁. In addition, the maximum deviation angle 505 denotes an angle whereby each modulation point includes as many noise components as a conventional DMB demodulator can demodulate without interference from another modulation point. Therefore, it is very important to set the optimum deviation angle that improves transmission efficiency while minimizing noise components.

When a link limit of SNR in which a conventional DMB system can perform communication is 4 dB and performance deterioration is 1.5 dB, a deviation angle experimentally determined according to the present invention is about 15 degrees. When the performance deterioration is 1.0 dB, the deviation angle may be about 11 degrees.

Here, the performance deteriorations are just experimental values and thus a different value may be applied according to an actual environment of each satellite DMB system.

In addition, when there exists a hierarchical 8PSK demodulator corresponding to the hierarchical 8PSK modulation scheme, all signals can be demodulated and received.

FIG. 6 illustrates a transmitter and a receiver of a satellite DMB system according to an exemplary embodiment of the present invention.

Referring to FIG. 6, a first DMB signal 601 is encoded by a Reed-Solomon encoder 602 in the unit of 188 bytes. Here, the Reed-Solomon encoder 602 adds 16 bytes to the received signal 601 and transfers it to a byte interleaver 605 having a depth of 12 and operating in a unit of a byte. The signal mixed by the byte interleaver 605 is re-encoded by a convolution encoder 607, and a bit interleaver 609 having a depth of 52 mixes the re-encoded signal in the unit of a bit. Subsequently, a CDM multiplexer 611 code-division multiplexes the mixed signal using a 64 Walsh code and a Pseudo Noise (PN) code. Then, the multiplexed signal is modulated by a hierarchical 8PSK modulator 613 and transmitted.

Meanwhile, an additional signal 615, which provides additional information in DMB broadcasting, is encoded by a second encoder 617. The second encoder 617 can perform different encoding according to characteristics of a signal or configurations. A bit interleaver 619 mixes the encoded additional signal 615 in the unit of a bit. Subsequently, the mixed signal is code-division multiplexed and hierarchically 8PSK modulated together with the satellite DMB signal, and is transmitted.

The modulated signal is received by a receiver, and first, a hierarchical 8PSK demodulator 621 separates the satellite DMB signal and the additional signal. Subsequently, a CDM demultiplexer 623 demultiplexes the respective code-division multiplexed signals. Here, the satellite DMB signal is passed through a bit deinterleaver 625, a Viterbi decoder 627, a byte deinterleaver 629 and a Reed-Solomon decoder 631, and thereby demodulated into an original satellite DMB signal 633.

Meanwhile, the additional signal is passed through a bit deinterleaver 625 and a second decoder 637, and thereby demodulated into an original additional signal 641. The second decoder 637 used here is previously determined to correspond to the second encoder 617 used in the transmitter.

According to the present invention, it is possible to provide a method and apparatus for hierarchical modulation in a digital broadcasting system.

In addition, according to the present invention, it is possible to provide a method of improving transmission efficiency through hierarchical modulation in a currently employed system.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method for hierarchical modulation in a digital broadcast signal transmitter, the method comprising the steps of:
(a) receiving a first broadcast signal and a second broadcast signal from outside, and encoding the broadcast signals by a first method and a second method, respectively;
(b) synthesizing the encoded first broadcast signal with the encoded second broadcast signal;
(c) determining a modulation point using a constellation diagram of an I-Q plane corresponding to the synthesized signal; and
(d) hierarchically phase-shift modulating the synthesized signal using the determined modulation point,
wherein in the I-Q plane, the modulation point is deviated by a predetermined deviation angle from a phase axis passing through a modulation point of the first broadcast signal and an origin of the I-Q plane.

2. The method of claim 1, wherein the first broadcast signal is demodulated by a Quadrature Phase Shift Keying (QPSK) demodulator and thus can be recognized, and the second broadcast signal is recognized as noise by the QPSK demodulator.

3. The method of claim 1, wherein the first broadcast signal has a higher restoration reliability indicating a possibility of being restored by a demodulator than the second broadcast signal.

4. The method of claim 1, wherein the first broadcast signal is a satellite digital broadcast signal, the first method is an encoding method for the satellite digital broadcast signal, the second broadcast signal is an additional information signal of the satellite digital broadcast signal, and the second method is an encoding method determined according to a type of the additional information signal.

5. The method of claim 1, wherein modulation performance for the hierarchically phase-shift-modulated first broadcast signal is determined according to the deviation angle.

6. The method of claim 5, wherein the deviation angle is determined in consideration of a limit of Signal-to-Noise Ratio (SNR) of the first broadcast signal.

7. The method of claim 1, wherein the encoding by the first method further comprises the steps of:
Reed-Solomon encoding; and
Code Division Multiplexing (CDM).

8. A method for hierarchical demodulation in a digital broadcast signal receiver, the method comprising the steps of:
receiving a digital broadcast signal from outside;
determining a demodulation point of the received digital broadcast signal using a constellation diagram of an I-Q plane corresponding to the received digital broadcast signal;
hierarchically phase-shift demodulating the received digital broadcast signal using the demodulation point;
separating the demodulated digital broadcast signal into a first broadcast signal and a second broadcast signal; and
demodulating the first broadcast signal by a digital broadcasting method and the second broadcast signal by a predetermined method,
wherein in the I-Q plane, the demodulation point is deviated by a predetermined deviation angle from a phase axis passing through a modulation point of the first broadcast signal and an origin of the I-Q plane.

9. The method of claim 8, wherein the deviation angle is determined in consideration of a limit of Signal-to-Noise Ratio (SNR) of the first broadcast signal.

10. A digital broadcast signal transmitter, comprising:
a Reed-Solomon encoder for encoding a first broadcast signal;
a byte interleaver for mixing the encoded first broadcast signal;
a convolution encoder for re-encoding the mixed first broadcast signal;
a first bit interleaver for remixing the re-encoded first broadcast signal;
a second encoder for encoding a second broadcast signal;
a second bit interleaver for mixing the encoded second broadcast signal;
a code division multiplexer for multiplexing the first and second broadcast signals output from the first and second bit interleavers; and
a hierarchical modulator for synthesizing and hierarchically phase-shift modulating the code-division multiplexed signals,
wherein, using a constellation diagram of an I-Q plane corresponding to the synthesized signal, the hierarchical modulator determines a modulation point in the I-Q plane deviated by a predetermined deviation angle from a phase axis passing through a modulation point of the first broadcast signal and an origin of the I-Q plane, and hierarchically phase-shift modulates the synthesized signal using the determined modulation point.

11. A digital broadcast signal receiver, comprising:
a hierarchical demodulator for, using a constellation diagram of an I-Q plane corresponding to a received digital broadcast signal, determining a point deviated by a predetermined deviation angle from a phase axis passing through a modulation point of a first broadcast signal and an origin of the I-Q plane, as a demodulation point of the received digital broadcast signal, and hierarchically phase-shift demodulating the received digital broadcast signal using the demodulation point;
a code division demultiplexer for code-division demultiplexing the signal demodulated by the hierarchical demodulator into the first broadcast signal and a second broadcast signal;
a Reed-Solomon decoder for decoding the code-division demultiplexed first broadcast signal; and
a second demodulator for decoding the code-division demultiplexed second broadcast signal.
